(19) United States
(12) Patent Application Publication
(10) Pub. No.: US 2024/0393500 A1
(43) Pub. Date: Nov. 28, 2024

(54) EMBEDDED SILICON NANOSTRUCTURES FOR SHORT-WAVE-INFRARED (SWIR) METAOPTICS IMPLEMENTATION

(71) Applicant: STMicroelectronics International N.V., Geneva (CH)

(72) Inventors: Enrico Giuseppe CARNEMOLLA, Edinburgh (GB); James Peter Drummond DOWNING, Doune (GB); Matteo FISSORE, Edinburgh (GB)

(73) Assignee: STMicroelectronics International N.V., Geneva (CH)

(21) Appl. No.: 18/202,418

(22) Filed: May 26, 2023

(51) Int. Cl. G02B 1/00; G02B 27/00; G06F 30/12

(52) U.S. Cl. CPC G02B 1/002; G02B 27/0012; G06F 30/12; G02B 2207/101

(57) ABSTRACT

A metasurface optic, designed for short-wave infrared (SWIR) range devices, is formed of one or more unit cells with a specific arrangement of truncated cone-shaped subwavelength nanostructures, tailored to achieve various optical functionalities. The one or more unit cells are formed from a design set selected from among multiple different design sets, each of the multiple different design sets featuring truncated cones having a unique combination of height (800 nm to 1100 nm), sidewall angle (91° to) 93°, and pitch (550 nm to 750 nm), with base radius values of the truncated cones within a given design set varying from 75 nm to 250 nm in 1 nm increments.

### TECHNICAL FIELD

This disclosure relates to the field of optics, specifically to the design, fabrication, and use of metasurface optics in various applications.

### BACKGROUND

Integrated optical components have become increasingly common in various devices, such as mobile phones, laptops, and appliances. These components provide functionalities such as face recognition, proximity detection, and ambient light sensing using time-of-flight (TOF) sensors. Typically, TOF sensors use diffractive optical elements (DOEs) to manipulate the output wavefront of a vertical cavity surface emitting laser (VCSEL) into a specific far-field intensity profile.

Although traditional optical elements such as lenses, mirrors, and prisms are widely used in optics, they may not always provide the desired degree of control over the properties of incident light. In such instances, metasurface optics have gained attention as a promising alternative to traditional optics. Metasurface optics are ultrathin planar structures formed of unit cells made of subwavelength nanostructures. The functionality of metasurface optics is determined by the geometry, size, and arrangement of the unit cells.

Metasurface optics function by inducing a spatially varying phase shift across the incident light. By carefully controlling the phase shift distribution, the metasurface optic can selectively modify the polarization of the wave in different ways. For example, a metasurface optic can be designed to focus or deflect the incident light by inducing a phase gradient across the wavefront. Similarly, a metasurface optic can change the polarization of the incident light by inducing a specific phase shift between the two orthogonal polarization components of the incident light. Holography, which involves the reconstruction of a three-dimensional image from a two-dimensional wavefront, can also be achieved using metasurface optics. In this case, the phase profile of the metasurface optic is designed to encode the information about the 3D object that is being reconstructed. By illuminating the metasurface optic with a reference wave and a signal wave that contains the information about the object, the metasurface optic can interfere the two waves and produce a holographic image.

Metasurface optics offer a high degree of control over the propagation of light, enabling the design of compact and efficient optical systems that are not possible with traditional optics. In addition to TOF sensors, metasurface optics have potential applications in sensing, high-speed communication, imaging, and energy conversion.

Advancements in nanofabrication techniques hold the potential to make it possible to produce metasurface optics on a large scale. However, there is still a need for further development in metasurface optic design in order to realize this potential. Specifically, there is a need for methods to select the constituent nanostructures of the unit cells to achieve specific properties required for various applications. Methods for the fabrication and use of metasurface optics are therefore disclosed herein, as are specific metasurface optics for use in specific applications.

### SUMMARY

Disclosed herein is a metasurface optic formed of one or more unit cells, each containing a specific arrangement of subwavelength nanostructures. These nanostructures are truncated cones with a height between 800 nm and 1100 nm and a sidewall angle between 91° and 93°. The distance between the axes of symmetry of each truncated cone nanostructure ranges from 550 nm to 750 nm, with certain truncated cones having a different base radius than others. The metasurface optic introduces a spatially varying phase shift across incident short-wave infrared (SWIR) light waves. At least one of the unit cells may be formed of an arrangement of subwavelength nanostructures into a rectangular pattern, hexagonal pattern, triangular pattern, radial pattern, or polygonal pattern.

In one embodiment, the nanostructures are made of polysilicon and embedded within a silicon dioxide body. The metasurface optic may also include a layer of silicon nitride stacked on the first face of the body, and an anti-reflective coating stacked on the silicon nitride layer.

The SWIR light waves interacting with the metasurface optic have a wavelength between 1260 nm and 1460 nm, or more specifically between 1360 nm and 1380 nm. In some cases, the sidewall angle of the nanostructures is approximately 92°.

Also disclosed herein is a method of making a metasurface optic. This method involves selecting a design set of fabricable nanostructure elements using a lithography process. Each nanostructure element in the design set is a truncated cone with the same height, substantially same or similar sidewall angle, and same spacing between the axes of symmetry, but with different base radii. The method proceeds with designing a unit cell containing a specific arrangement of nanostructures from the selected design set, and using this unit cell to design a metasurface optic. The designed metasurface optic is then translated into a CAD layout, which is used to fabricate the metasurface optic.

In some embodiments, the selected design set includes truncated cone nanostructures with a height between 800 nm and 1100 nm, a sidewall angle between 91° and 93°, and an intended spacing between the axes of symmetry ranging from 550 nm to 750 nm. The radii of the truncated cone nanostructures may vary between 75 nm and 250 nm with a step size of 1 nm. In certain cases, the sidewall angle is approximately 92°. The nanostructures may be formed of polysilicon embedded within a body of silicon dioxide, with a layer of silicon nitride stacked on the first face of the body. Depending on design, the metasurface optic dimensions may be based upon a selected number of unit cell repetitions.

Also disclosed herein is an optic, including an arrangement of subwavelength nanostructures, with the nanostructures being truncated cone nanostructures having a same height of between 800 nm and 1100 nm and a sidewall angle selected from 91° to 93°, and with a same spacing between axes of symmetry of each truncated cone nanostructure being between 550 nm and 750 nm. A base of certain of the truncated cone nanostructures has a different radius than others of the truncated cone nanostructures.

The truncated cone nanostructures may be formed of polysilicon and are embedded within a body of silicon dioxide. A layer of silicon nitride may be stacked on a first face of the body, and an anti-reflective coating stacked on the silicon nitride layer. In addition, the sidewall angle may be approximately 92°.

### BRIEF DESCRIPTION OF THE DRAWINGS

FIG. 1 shows a block diagram of a system for creating a metasurface optic as described in this document.

FIG. 2 provides an enlarged diagrammatical cross-sectional view of a metasurface optic formed using the system of FIG. 1.

FIG. 3 contains graphs displaying the transmission and reflection performance of a particular design set described in this document.

FIG. 4 shows a top view of the unit cell of the metasurface optic depicted in FIG. 3.

FIG. 5 is a diagrammatical perspective view of a time-of-flight ranging module that includes the metasurface optic shown in FIG. 3.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Described herein are metasurface optics that have been found to be particularly useful in devices operating in the short-wavelength infrared (SWIR) range of light (e.g., 1260 nm to 1460 nm in wavelength, or 1360 nm to 1380 nm in wavelength).

Recall that metasurface optics are ultrathin planar structures formed of unit cells made of subwavelength nanostructures and that metasurface optics are engineered to introduce a spatially varying phase shift across an incident light wave, which enables a wide range of optical functionalities. The components of a unit cell of a metasurface optic, such as nano-antennas, resonators, or dielectric structures, cause the phase shifts by modifying the amplitude and phase of the electric and magnetic fields of the incident electromagnetic wave. The individual unit cells are arranged in a specific pattern that controls the amplitude and phase of the light wave. The exact mechanism by which this control is achieved depends on the specific design of the metasurface optic and the properties of the individual unit cells, but in general, the unit cells of the metasurface optic can affect the phase of the incident light in several ways.

First, the unit cells may introduce a phase delay by using resonant nanostructures or nanosized waveguides that introduce a delay in the propagation of the incident light. The delay can be controlled by adjusting the specific geometry and material properties of the unit cells. Second, the unit cells may introduce a phase gradient by arranging the unit cells in a specific pattern that creates a gradual change in the phase of the incident light. This can be used, for example, to focus or deflect the wave. Third, the unit cells may induce a polarization rotation: Some types of unit cells can rotate the polarization of the incident light, which in turn can induce a phase shift. This can be used for polarization conversion or other optical functions.

Overall, the precise mechanism by which the unit cells of a metasurface optic induce phase shifts depends on the specific design of the metasurface optic and the properties of the individual unit cells, and the precise control of the phase shift distribution across the metasurface optic is of particular interest for achieving the desired optical function. The metasurface optic design can involve complex optimizations to tailor the phase shift distribution to achieve the desired optical function with high efficiency and fidelity.

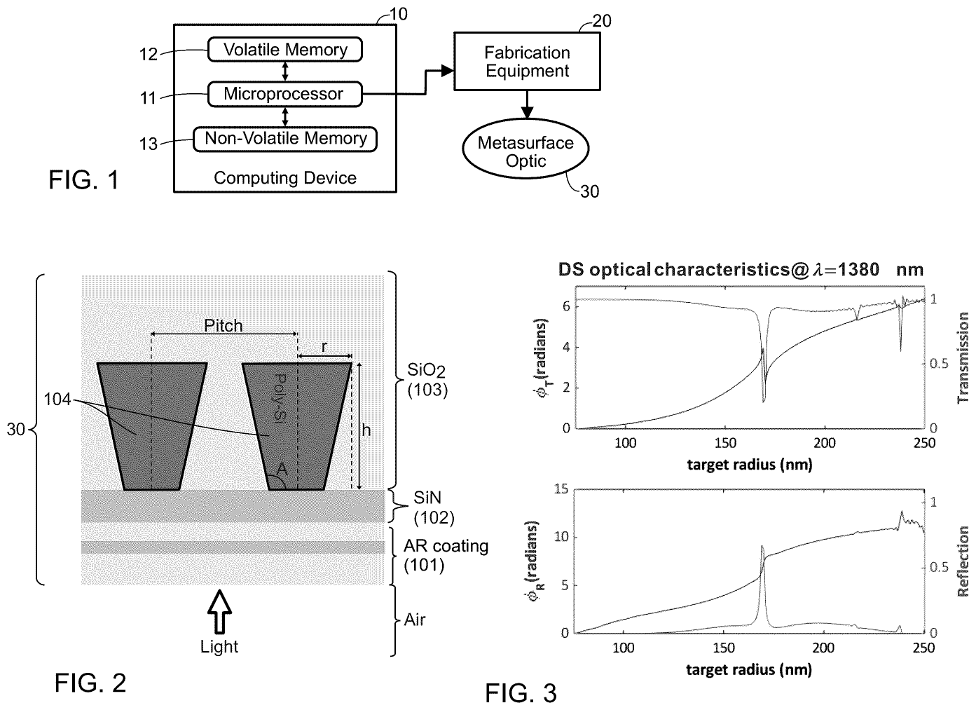

The following process outlines the creation of a metasurface optic 30 using a computing device 10 and fabrication equipment 20 as depicted in FIG. 1. The computing device 10 comprises a microprocessor 11, volatile memory 12, and non-volatile memory 13, with the microprocessor 11 executing stored instructions to generate information for use by the fabrication equipment 20 in producing the metasurface optic 30. The computing device 10 may be, for example, a desktop computer, a laptop computer, a server, etc.

In designing the metasurface optic and its unit cells, a suitable design set from which the nanostructures of the unit cells are selected is chosen from among multiple such design sets. These design sets are stored in the non-volatile memory 13 and/or volatile memory 12 of the computing device 10. Each design set is formed of multiple elements, each element being a different truncated cone, with every element of the design set differing by a single same design aspect or dimension (e.g., the radius of the base of the cone). The choice of design set may be based on criteria such as transmission efficiency, reflection characteristics, and tolerance to fabrication imperfections.

For purposes of understanding the truncated cones and their design aspects or dimensions, refer now to FIG. 2, showing two truncated cones 104 each having a height, a radius, and sidewall angle (the angle between the sidewall and the truncated top of the cone). Another aspect within each design set is the pitch, which is the distance between the axes of symmetry of different nanostructure elements within a unit cell to be formed utilizing that given design set.

Each design set considered for selection is specifically tailored for the short-wave infrared (SWIR) range and comprises a collection of truncated cone nanostructures. Within a design set, the base radius of these truncated cones varies from 75 nm to 250 nm in increments of 1 nm. However, each design set features a height, sidewall angle, and pitch for all its truncated cones. The height of the truncated cones in a given design set may be from 800 nm to 1100 nm, with the truncated cones within in the design set being of the same height, and with different design sets potentially having different heights within this range of 800 nm to 1100 nm. The sidewall angle, which is the angle between the sidewall and the truncated top of the cone, varies from 91° to 93° (and may vary from design set element to design set element dependent on base radius) and is ultimately matched to the manufacturing process capability. Additionally, the pitch, which represents the distance between the axes of symmetry of different nanostructure elements within a unit cell formed using a given design set, varies from 550 nm to 750 nm across design sets. Note that while the height, sidewall angle, and pitch values are the same or substantially similar (in the case of sidewall angle) within each design set, they differ from one design set to another. No two design sets share identical values for all three parameters (height, sidewall angle, and pitch). This variety ensures a range of optical characteristics across different design sets, providing flexibility in selecting the most suitable design set for the desired application. The optical characteristics of a specific design set, such as its transmission and reflection properties, can be visualized through graphs provided in FIG. 3.

These design sets described above have been optimized for robustness and tolerance to fabrication imperfections. This helps increase the likelihood that minor variations in the dimensions or alignment of the nanostructures during the fabrication process do not significantly impact the overall optical performance of the metasurface optic. This robust design enables consistent performance across multiple fabricated samples and reduces the likelihood of defects.

The use for the selected design set is in the design of a unit cell. Therefore, after choosing the appropriate design set, the next step involves designing a unit cell. This unit cell is a specific arrangement of nanostructures from the chosen design set. Once the unit cell design is complete, the dimensions of the metasurface optic 30 are determined. In some applications, a single such unit cell may span the entire metasurface optic 30 to provide the metasurface optic 30 with the desired optical properties, and the metasurface optic 30 may have desired dimensions suitable for its intended usage. In other applications, the unit cell is repeated across the metasurface optic 30 in a desired pattern to create the desired optical properties, and in these cases, the dimensions of the metasurface optic are determined based on the number of unit cell repetitions needed to achieve the intended functionality and size.

Following the establishment of the unit cell and metasurface optic 30 design, the microprocessor 11 is responsible for translating this design into a format suitable for fabrication. The microprocessor 11 converts the metasurface optic design into a computer-aided design (CAD) layout, which encodes the specific desired arrangement of nanostructures forming the metasurface optic 30. This CAD layout is then used to define the mask for the subsequent fabrication steps.

An electron-beam lithography process, performed by the microprocessor 11 suitably controlling the fabrication equipment 20, transfers this design onto the mask by scanning the electron beam across the surface and selectively exposing the resist to define the metasurface optic design. This mask is then utilized for the photolithography process. Indeed, following mask formation, a material deposition process is conducted, after which the mask is used in the photolithography step to transfer the design onto a substrate. Further material deposition steps and other processing measures are then conducted as required by the specific design.

Referring back to FIG. 2, the metasurface optic 30, as fabricated, comprises a body 103 made of silicon dioxide (SiO2). A layer of silicon nitride (SiN) 102 is deposited on a first face of the body 103, followed by an anti-reflective coating 101 applied on top of the silicon nitride layer 102. The anti-reflective coating 101 may have a refractive index that corresponds to a wavelength range of 1340 nm to 1400 nm, potentially improving total transmission of the metasurface optic 30 by 4%-5% (in the case that the metasurface optic 30 is utilized for transmission). The anti-reflective coating 101 may be optional, for example in the case where the metasurface optic 30 is used for reception.

Embedded within the body 103 are nanostructures 104, shaped as truncated cones and comprised of polysilicon. The selection of silicon dioxide for the body, silicon nitride for the layer on the first face of the body 103, and polysilicon for the nanostructures 104 was based on multiple factors—these materials possess desirable optical properties within the near-infrared and short wave infrared ranges, are compatible with lithographic fabrication processes, and offer cost-effectiveness for manufacturing purposes.

In accordance with the design sets previously mentioned, the nanostructures 104 are configured as truncated cones with specific characteristics. The sidewall angle (A), defined as the angle between the sidewall and the truncated top of the cone, ranges from 91° to 93°. The height of the cones varies from 800 nm to 1100 nm, while the base radius spans from 75 nm to 250 nm, with a step size of 1 nm. The pitch, which refers to the distance between the axes of symmetry of adjacent nanostructure elements within a unit cell, lies between 550 nm and 750 nm.

Note that, although ranges for the sidewall angle, height, radius, and pitch are provided, the sidewall angle, height, and pitch are consistent for each nanostructure 104 within the body 103, with sidewall potentially varying a small amount dependent upon radius. However, the radius can differ among nanostructures 104 within the body 103, allowing for variations in the metasurface optic's properties and performance.

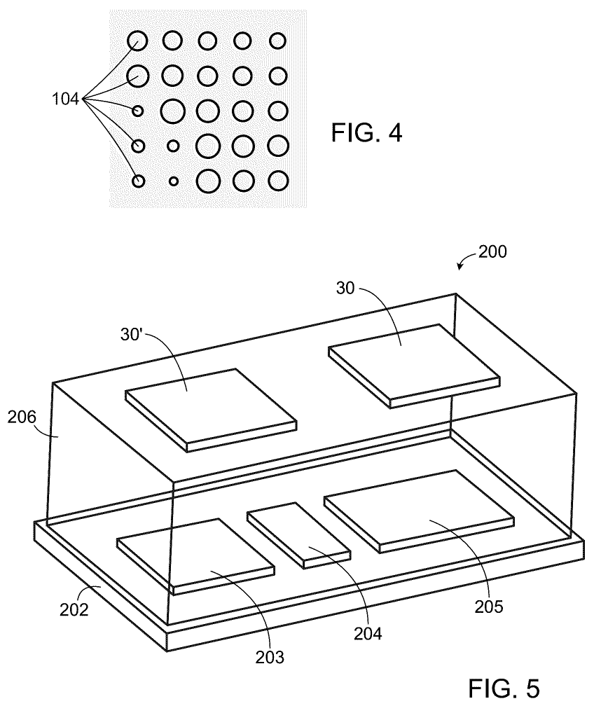

Since the specifics of the nanostructure have already been given, the specifics of the unit cells are now given. A top view of one of the unit cells of the nanostructure optic 103 is shown in FIG. 4, where it can be observed that the unit cell is formed of a square pattern of the nanostructures 104. For ease of understanding, consider a grid of equally spaced dots arranged into rows and columns and then consider a nanostructure 104 being formed at each dot (with the dot being the center point of truncated cone). The square pattern of nanostructures in the unit cell, as shown in FIG. 4, is one embodiment and has the ability to provide high transmission efficiency and a well-defined phase shift distribution across the metasurface optic 30. This arrangement enables precise control of the amplitude and phase of the incident light, which is essential for achieving the desired optical functionality. Other patterns of nanostructures in a unit cell may be used, such as a rectangular pattern, hexagonal pattern, triangular pattern, radial pattern, polygonal pattern, or other suitable pattern.

As may be appreciated, the metasurface optic 30 may be utilized in a wide variety of applications. For example, a sample time-of-flight (TOF) module 200, which incorporates the metasurface optic 30, is described with reference to FIG. 5. The sample TOF module 200 comprises a substrate 202, serving as the base for the integrated components. Mounted on the substrate 202 is an array of vertical cavity surface emitting lasers (VCSELs) 205, a sensor 203 for detecting the reflected light, and a VCSEL driver 204 that controls the operation of the VCSELs.

To provide protection and maintain the integrity of the array of VCSELs 205, sensor 203, and VCSEL driver 204, a transparent layer 206 is applied on top of these components. The metasurface optic 30 is incorporated within the transparent layer 206 above the VCSELs 205, while another metasurface optic 30′ is embedded within the transparent layer 206 above the sensor 203. These metasurface optics enhance the performance of the TOF module 200 by shaping the emitted and received light.

During operation, the VCSEL driver 204 activates the array of VCSELs 205, causing them to emit pulses of collimated short-wave infrared (SWIR) light directed toward a scene. The collimated SWIR light first passes through the metasurface optic 30, which manipulates the light's properties before it enters the scene. If an object is present in the scene, the emitted collimated SWIR light bounces off the object and travels back to the TOF module 200. On its return journey, the reflected light passes through the metasurface optic 30′ before reaching the sensor 203.

Since the speed of light remains constant and known, it is possible to calculate the distance to the target object by measuring the elapsed time between the emission of a given pulse of collimated SWIR light by the array of VCSELs 205 and the detection of its reflection by the sensor 203 within the scene. This information can be used for various applications, such as depth sensing, object tracking, and 3D imaging.

While the preceding discussions have addressed the fabrication of metasurface optics using the described design sets, and the fabrication of devices utilizing those metasurface optics, it should be understood that this disclosure also extends to the design sets themselves. These design sets are configurations of nanostructures intended for the precise manipulation of incident light, particularly within the short-wavelength infrared (SWIR) range.

As explained above, each design set comprises a variety of truncated cone nanostructures, optimized for the SWIR range, differing in a single design aspect or dimension. The nanostructures within a design set exhibit a consistent height, substantially similar sidewall angle, and pitch, with varying base radius. The sidewall angle varies slightly within each design set based upon base radius. The selection of a specific design set for a metasurface optic is typically based on factors such as transmission efficiency, reflection characteristics, and tolerance to fabrication imperfections.

In this regard, the design sets represent a robust and flexible framework for the creation of optics with desired optical properties. They account for a wide range of optical characteristics, providing considerable versatility in the design of optics for varied applications. This covers the development and use of these design sets themselves, independent of their application in the formation of metasurface optics. The variety in design sets provides for a robust approach to the creation of metasurface optics, accommodating a broad spectrum of functionalities and applications.

It is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A metasurface optic, comprising:
one or more unit cells, each unit cell comprising a specific arrangement of subwavelength nanostructures;
said nanostructures being truncated cone nanostructures having a same height of between 800 nm and 1100 nm and a sidewall angle selected from 91° to 93°, with a same spacing between axes of symmetry of each truncated cone nanostructure being between 550 nm and 750 nm, wherein a base of certain of the truncated cone nanostructures has a different radius than others of the truncated cone nanostructures; and
said metasurface optic introducing a spatially varying phase shift across incident short-wave infrared (SWIR) light waves.

2. The metasurface optic of claim 1, wherein the truncated cone nanostructures are formed of polysilicon and are embedded within a body of silicon dioxide.

3. The metasurface optic of claim 2, further comprising a layer of silicon nitride stacked on a first face of the body, and an anti-reflective coating stacked on the silicon nitride layer.

4. The metasurface optic of claim 1, wherein the SWIR light waves have a wavelength of between 1360 nm and 1380 nm.

5. The metasurface optic of claim 1, wherein the sidewall angle is 92°.

6. The metasurface optic of claim 1, wherein the SWIR light waves have a wavelength of between 1260 nm and 1460 nm.

7. The metasurface optic of claim 1, wherein at least one unit cell is comprised of an arrangement of subwavelength nanostructures into a rectangular pattern, hexagonal pattern, triangular pattern, radial pattern, or polygonal pattern.

8. A method of making a metasurface optic, comprising:
selecting a design set including a plurality of nanostructure elements that are fabricatable using a lithography process, each nanostructure element being identical in each of their parameters except a same given parameter;
wherein the plurality of nanostructure elements in the selected design set are truncated cone nanostructures, with each nanostructure element being identical in height to each other nanostructure element but differing from each other nanostructure element by radius, and with an axis of symmetry of each nanostructure being spaced apart from axes of symmetry of adjacent nanostructures by a same given pitch in the metasurface optic after fabrication;
designing a unit cell comprising a specific arrangement of nanostructures from the selected design set;
designing a metasurface optic using the unit cell;
translating the designed metasurface optic into a CAD layout; and
using the CAD layout to fabricate the metasurface optic.

9. The method of claim 8, wherein the selected design set comprises:
truncated cone nanostructures each having a same height of between 800 nm and 1100 nm and a sidewall angle selected from 91° to 93°, with a same intended spacing between an axis of symmetry of each truncated cone nanostructure being between 550 nm and 750 nm, wherein a base of each of the truncated cone nanostructures has a different radius.

10. The method of claim 9, wherein the sidewall angle is 92°.

11. The method of claim 9, wherein the radii of the truncated cone nanostructures vary between 75 nm and 250 nm with a step size of 1 nm.

12. The method of claim 8, wherein the nanostructures are shaped as truncated cones and are formed of polysilicon embedded within a body of silicon dioxide, with a layer of silicon nitride being stacked on a first face of the body.

13. The method of claim 8, wherein the selected design set comprises truncated cone nanostructures each having a same height of between 800 nm and 1100 nm.

14. The method of claim 8, wherein the selected design set comprises truncated cone nanostructures each having a sidewall angle selected from 91° to 93°.

15. The method of claim 8, wherein the selected design set comprises truncated cone nanostructures each having a same intended spacing between an axis of symmetry of each truncated cone nanostructure being between 550 nm and 750 nm.

16. The method of claim 8, wherein the selected design set comprises truncated cone nanostructures, wherein a base of each of the truncated cone nanostructures has a different radius, wherein the radii of the truncated cone nanostructures vary between 75 nm and 250 nm with a step size of 1 nm.

17. The method of claim 8, wherein the metasurface optic has dimensions set based upon a selected number of unit cell repetitions.

18. The method of claim 8, wherein the unit cell is designed as an arrangement of nanostructures from the selected design set into a rectangular pattern, hexagonal pattern, triangular pattern, radial pattern, or polygonal pattern.

19. A metasurface optic, consisting of:
one or more unit cells, each unit cell comprising a specific arrangement of subwavelength nanostructures;
said nanostructures being truncated cone nanostructures having a same height of between 800 nm and 1100 nm and a sidewall angle selected from 91° to 93°, with a same spacing between axes of symmetry of each truncated cone nanostructure being between 550 nm and 750 nm, wherein a base of certain of the truncated cone nanostructures has a different radius than others of the truncated cone nanostructures, wherein the radii of the truncated cone nanostructures vary between 75 nm and 250 nm with a step size of 1 nm; and
said metasurface optic being introducing a spatially varying phase shift across incident short-wave infrared (SWIR) light waves which have a wavelength of between 1360 nm and 1380 nm.

20. The metasurface optic of claim 19, wherein the sidewall angle is approximately 92°.

21. The metasurface optic of claim 19, wherein the nanostructures are formed of polysilicon and are embedded within a body of silicon dioxide.

22. The metasurface optic of claim 21, wherein a layer of silicon nitride is stacked on a first face of the body, and an anti-reflective coating is stacked on the silicon nitride layer.

23. An optic, comprising:
an arrangement of subwavelength nanostructures, said nanostructures being truncated cone nanostructures having a same height of between 800 nm and 1100 nm and a sidewall angle selected from 91° to 93°, with a same spacing between axes of symmetry of each truncated cone nanostructure being between 550 nm and 750 nm, wherein a base of certain of the truncated cone nanostructures has a different radius than others of the truncated cone nanostructures.

24. The optic of claim 23, wherein the truncated cone nanostructures are formed of polysilicon and are embedded within a body of silicon dioxide.

25. The optic of claim 24, further comprising a layer of silicon nitride stacked on a first face of the body, and an anti-reflective coating stacked on the silicon nitride layer.

26. The optic of claim 23, wherein the sidewall angle is approximately 92°.
